(19) United States
(12) Patent Application Publication
(10) Pub. No.: US 2026/0181860 A1
(43) Pub. Date: Jun. 25, 2026

(54) MEMORY CELL AND OPERATION OF THE MEMORY CELL

(71) Applicant: Forschungszentrum Jülich GmbH, Jülich (DE)

(72) Inventors: Qing-Tai Zhao, Jülich (DE); Yi Han, Jülich (DE); Detlev Grützmacher, Niederzier (DE)

(21) Appl. No.: 19/132,710

(22) PCT Filed: Oct. 31, 2023
(86) PCT No.: PCT/EP2023/080339

§ 371 Date: May 23, 2025

(30) Foreign Application Priority Data
Nov. 25, 2022 (DE) 102022212598.3

(51) Int. Cl. H10B 12/00; G11C 11/404

(52) U.S. Cl. CPC H10B 12/20; G11C 11/404; G11C 2211/4016

(57) ABSTRACT

The invention relates to a memory cell comprising a layer (101) for collecting charge carriers at a surface of the layer (101), an electrically insulating layer (102) on the surface provided for collecting charge carriers, a lightly doped semiconducting layer (103) on the electrically insulating layer (102), a dielectric layer (106) on the lightly doped semiconducting layer (103), an electrical contact (107) serving as a gate terminal on the dielectric layer (106), an electrical contact serving as a source terminal (105a), an electrical contact serving as a drain terminal (105b), wherein the dielectric layer (106) is located between the source terminal (105a) and the drain terminal (105b).

The invention relates to a method for operating such a memory cell.

The memory cell can be operated at cryogenic temperatures and can store more than two different states.

The invention relates to a memory cell and a method for operating the memory cell.

A conventional DRAM (dynamic random-access memory) cell consists of a transistor and a capacitor (1T1C). The transistor may be a field-effect transistor. A field-effect transistor comprises three terminals called source, gate and drain. By applying a voltage to the gate terminal, an electric current flowing from the source terminal to the drain terminal can be controlled.

Information can be stored by the capacitor. To electrically charge the capacitor for storing information, a voltage can be applied to the gate terminal, i.e., to the gate. An electric current then flows through the transistor, namely from the source terminal to the drain terminal. Such a current charges the capacitor. The charged state of the capacitor can be regarded as state “1”. The uncharged state of the capacitor can be regarded as state “0”. A DRAM memory cell can therefore be used to store information digitally.

The transistor serving as a switch can also be used to read the charge state of the capacitor and thus the information stored in the DRAM memory cell. The 1T1C DRAM has a disadvantage for high-density integration due to the large-area capacitor.

SOI transistors are known from the prior art. SOI transistors are categorized into FD-SOI transistors and PD-SOI transistors. PD-SOI transistors have a relatively thick SOI layer, which can be at least 50 nm thick. FD-SOI transistors have a thin SOI layer, which can be thinner than 40 nm. FD-SOI transistors with a very thin SOI layer have a so-called “ground plain” below an electrically insulating layer. Such a transistor cannot store information and is therefore not a memory cell.

The task of the invention is to further develop a memory cell.

The task is solved by a memory cell with the features of the first claim. The additional claim relates to a method for operating the memory cell. The dependent claims relate to advantageous embodiments.

A memory cell with a layer for collecting charge carriers on a surface of the layer is used to solve the task. The collected charge carriers can be electrons or electron holes (holes). A layer means a two-dimensional mass of a substance that can be located above, below or between something else. The length and/or width of the layer can be greater than the thickness of the layer. Collecting charge carriers such as electrons at a surface means that by applying a voltage to an electrical connection of the memory cell provided for this purpose, charge carriers such as electrons can be collected at a surface of the layer. If charge carriers have been collected on a surface, then there is a surface area of the layer with an increased concentration of charge carriers, for example, with an increased electron concentration compared to adjacent sections. This surface area is then electrically charged, i.e., negatively charged in the case of electrons. An adjacent surface area can then be charged in the opposite direction, for example, positively charged by an increased concentration of electron holes. Collection is generally achieved by applying an electric field to the layer. The layer for collecting charge carriers generally consists of a semiconductor, in particular a lightly doped semiconductor. A semiconductor is a solid body with an electrical conductivity that lies between the electrical conductivity of electrical conductors and the electrical conductivity of electrical insulators, i.e., electrical non-conductors. The electrical conductivity of a semiconductor can be less than 10⁴ S/cm and greater than 10⁻⁸ S/cm. The electrical conductivity of a semiconductor increases with rising temperature.

There may be an electrically insulating layer on the surface provided for collecting charge carriers. An electrically insulating layer consists of an electrically nonconductive material. The electrical conductivity of the electrically nonconductive material can be less than 10⁻⁸ S/cm. In principle, there is no intermediate layer between the electrically insulating layer and the layer for collecting charge carriers. Hafnium oxide, zirconium oxide or aluminum oxide may form the electrically insulating material.

A lightly doped (low-doped) semiconducting layer may be present on the electrically insulating layer. The lightly doped, semiconducting layer may act like a channel in a transistor. The lightly doped, semiconducting layer is then formed from a semiconductor, wherein the semiconductor is doped. To do this, foreign atoms have been brought into the semiconductor. In the case of doping, the amount of foreign atoms is very small compared to the amount of semiconductor. After doping, the proportion of foreign atoms in the semiconductor can be between 0.1 and 100 ppm, wherein ppm means “parts per million”. The foreign atoms form defects in the semiconductor and change the electrical conductivity of the semiconductor.

A dielectric layer can be located on the lightly doped semiconducting layer. “On” means that there is generally no intermediate layer between the two layers. The dielectric layer is made of a dielectric material. It can be a dielectric material that is used for a gate oxide in a MOSFET. The dielectric material has a high electrical resistivity and can therefore conduct an electrical charge hardly or not at all. The dielectric layer may, for example, consist of Al₂O₃, HfO₂, ZrO₂ or Si₃N₄.

An electrical contact serving as a gate terminal may be located on the dielectric layer. The dielectric layer may be located between a source terminal and a drain terminal of the memory cell. The source terminal and drain terminal each form an electrical contact of the memory cell. By applying a voltage to the gate terminal or gate, a current flow from the source terminal to the drain terminal can be regulated. An electrical contact consists of an electrically conductive material. The electrical conductivity of an electrical contact can be more than 10⁴ S/cm. In principle, the electrically conductive material exhibits an overlap between the valence band and the conduction band.

Such a memory cell can be particularly small. It is possible to achieve 10 nm technology nodes and smaller. Unlike the DRAM memory cell described at the beginning, no capacitor is needed in addition to a transistor. The tunability of the threshold voltage is very good when charge carriers are collected. This very good tunability can be achieved in particular if the electrically insulating layer is very thin. It is possible to use such a memory cell not only to store two states, “0” and “1”, but also other states. In this sense, information can be stored in analog form and not just in digital form. Such a memory cell can be operated at very low, cryogenic temperatures. Such a memory cell can be part of a quantum computer, for example a quantum computer that is operated at temperatures close to 0 Kelvin, i.e., close to absolute zero. Thus, the memory cell can be operated at temperatures of less than 77 Kelvin or 77 K, for example at temperatures of a few 100 mK or at temperatures from 3 K to 8 K.

The source terminal may be separated from the dielectric layer by a highly doped (heavily doped) semiconductor. The drain terminal may be separated from the dielectric layer by a highly doped semiconductor. The highly doped semiconductor can form a layer that is a single intermediate layer between the source terminal and the dielectric layer and/or a single intermediate layer between the drain terminal and the dielectric layer. There is then only the highly doped semiconductor between the source terminal and the dielectric layer and/or between the drain terminal and the dielectric layer. This helps to avoid an unfavorable Schottky contact that makes it difficult to read information. However, the memory cell may also have a Schottky contact with a very small Schottky barrier, in order to be able to do without the separating highly doped semiconductor relatively easily.

A lightly doped, semiconducting layer or a lightly doped semiconductor is doped by at least one order of magnitude or at least two orders of magnitude less than a highly doped, semiconducting layer or a highly doped semiconductor.

Semiconductors that are particularly suitable for the memory cell are silicon or germanium. Particularly suitable semiconductors are also group IV or group III-V semiconductor alloys. Examples of suitable semiconductor alloys are silicon carbide (SiC) or germanium-tin (GeSn).

The source and/or drain terminals may be located directly on the electrically insulating layer. In this case, there is no intermediate layer between the electrically insulating layer and the source and/or drain terminal. However, it is also possible that the source terminal is separated from the electrically insulating layer by a highly doped semiconductor. The drain terminal may also be separated from the electrically insulating layer by a highly doped semiconductor. The highly doped semiconductor may be a single intermediate layer between the electrically insulating layer and the source terminal and/or the drain terminal.

The dielectric layer may be thinner than 50 nm or thinner than 30 nm. The dielectric layer can be at most 20 nm or at most 15 nm thick. The dielectric layer can be at least 1 nm or at least 5 nm thick. By means of an especially thin dielectric layer, some of the mentioned properties of the memory cell can be further improved.

The layer for collecting charge carriers may be the substrate of the memory cell. Substrate means a self-supporting layer to which the other layers of the memory cell have been applied. The substrate may be thicker than any other layer of the memory cell.

The layer for collecting charge carriers may be formed from a lightly doped semiconductor.

The electrically insulating layer can be formed from silicon dioxide, Si₃N₄, or high-k dielectrics such as HfO₂, Al₂O₃, ZrO₂, Lu₂O₃, LaLuO₃, GdScO₃, LaSCO₃.

Lightly doped silicon can be used as the lightly doped semiconductor.

The gate, source and/or drain terminals may be formed from metal. The gate, source and/or drain terminals may be formed from silicide or metallic materials such as Cu, Ni, Ti, Al, Pt, Cr, W, TiN. The gate, source and/or drain terminals may be formed from highly doped semiconductor.

A lightly doped semiconducting layer may have a doping of no more than 1e17 cm⁻³. A highly doped semiconducting layer can have a doping of at least 1e18 cm⁻³ or at least 1e19 cm³. A lightly doped semiconducting layer can thus be doped at least three orders of magnitude less than a highly doped semiconducting layer.

The memory cell may be configured such that information can be stored in the memory cell and/or information can be read out of the memory cell by applying an electrical voltage to the drain terminal, wherein the magnitude of the electrical voltage for reading out is lower than the magnitude of the electrical voltage for storing information. The term “magnitude” refers to the distance of the number for the voltage given in volts on the number line from zero. During the reading of information, a voltage applied to the gate terminal can be changed, for example, it can be increased or decreased linearly. There is therefore a threshold. The state of the memory cell can be changed if the magnitude of the applied voltage is above the magnitude of the threshold. If a voltage is applied that is below the threshold voltage in terms of magnitude, the state of the memory cell is not changed. However, such a voltage can be used to read the state of the memory and thus the stored information.

The memory cell can be configured such that information can be stored in the memory cell by applying an electrical voltage to the drain terminal in the form of electrical pulses, and the stored information depends on the number of pulses. With each pulse, charge carriers are collected at the surface for collecting charge carriers. The number or magnitude of collected charge carriers can therefore depend on the number of pulses. The memory cell can therefore behave like a biological synapse. The memory cell can therefore be part of an artificial neural net.

A pulse may be at least 10 ns or at least 50 ns long. A pulse may be at least no longer than 100 ms or at least no longer than 10 ms long. The time between two pulses may be at least 10 ns or at least 50 ns. The time between two pulses may be no more than 10 s or no more than 5 s.

The memory cell may be configured such that information can be stored in the memory cell by applying a voltage to both the source terminal and the drain terminal at the same time. This can be in the form of one or more pulses.

The invention also relates to a method for operating the memory cell. Information is stored in the memory cell and/or information is read out of the memory cell by applying an electrical voltage to the drain terminal. The magnitude of the electrical voltage for reading is lower than the magnitude of the electrical voltage for storing information. During the reading of information, a voltage applied to the gate terminal is changed.

Information in the memory cell can be erased by applying a voltage to the drain terminal whose polarity is opposite to the polarity of the voltage for storing the information. The voltage required for erasing may be greater than the voltage required for writing, with the same pulse width. With the same voltage, the pulse width for erasing may be greater than the pulse width for writing.

Information can be stored in the memory cell by applying an electrical voltage in the form of several electrical pulses to the drain terminal.

Information stored in the memory cell can depend on the number of pulses. In this sense, information can be stored in analog form.

The memory cell can be operated at a cryogenic temperature of less than −200° C. or less than −250° C. The lower the temperature, the better the charge carriers collected when storing information can be held without having to re-store stored information at regular intervals. It is therefore preferable for the memory cell to be operated at very low temperatures, such as near absolute zero.

The voltage applied to the drain terminal for storing information and for reading information can be negative if the highly doped, semiconducting layer is p-doped. The voltage applied to the drain terminal for storing information and for reading information can be positive if the highly doped, semiconducting layer is n-doped.

The invention is explained in more detail with reference to the following figures. The figures show examples of possible configurations of the invention. The figures show:

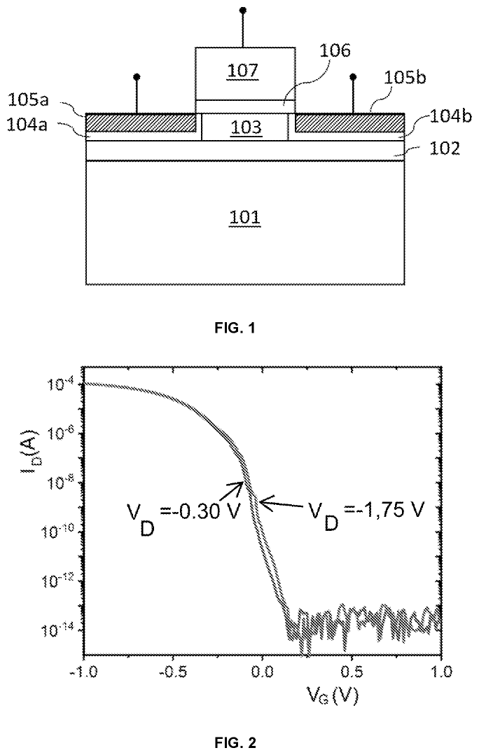

FIG. 1: cross-section through a first memory cell;

FIG. 2: current-voltage curve of the memory cell;

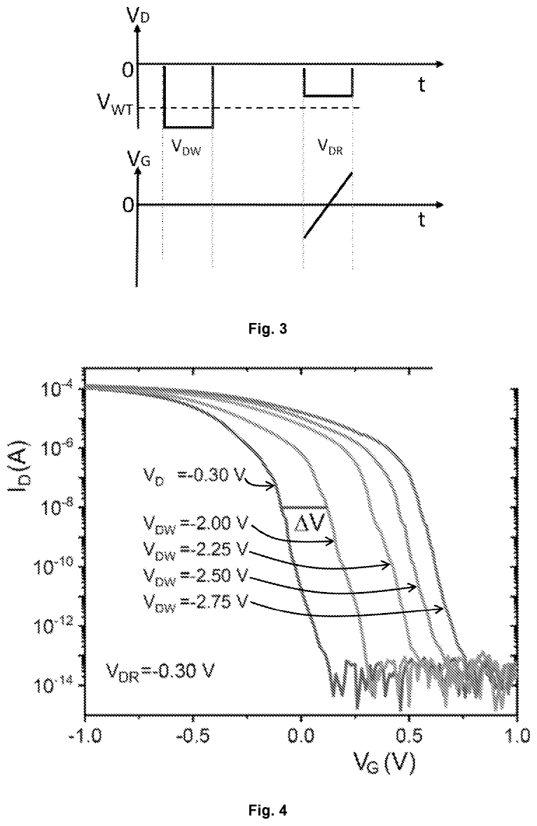

FIG. 3: write pulse and read pulse;

FIG. 4: current-voltage curves of the memory cell due to write pulses;

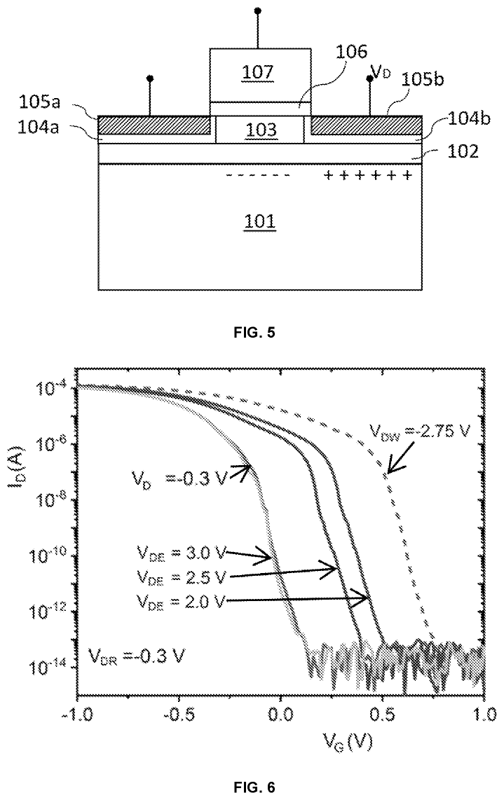

FIG. 5: cross-section through the first memory cell after a write pulse;

FIG. 6: Current-voltage curves of the memory cell due to erasing pulses;

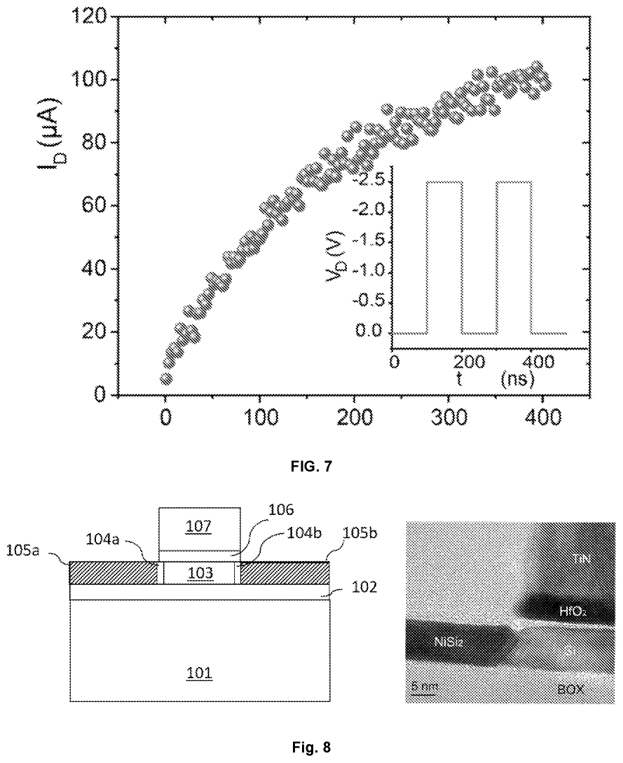

FIG. 7: States of the memory cell due to a large number of write pulses;

FIG. 8: Cross-section of a second memory cell and corresponding electron micrograph;

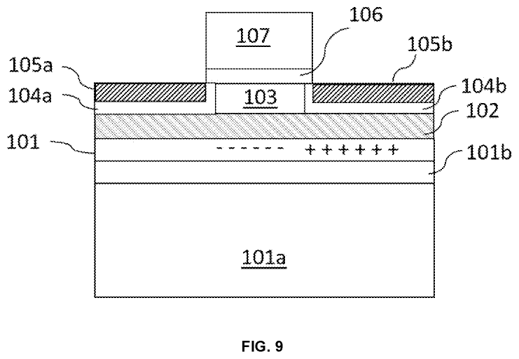

FIG. 9: Cross-section of a third memory cell.

FIG. 1 shows a section through a first memory cell. A substrate 101 of the memory cell is a layer for collecting charge carriers at a surface of the layer. An electrically insulating layer 102 is applied to the upper side of the layer 101. The electrically insulating layer 102 may be formed from silicon dioxide. The electrically insulating layer 102 may be very thin. The thickness of the electrically insulating layer 102 may be less than 40 nm or less than 20 nm. The electrically insulating layer 102 may be realized by “buried oxide”, also known as “BOX”. A layer 103 is applied to the upper side of the electrically insulating layer 102, which is formed from a lightly doped semiconductor. The lightly doped, semiconducting layer 103 may be formed from lightly doped silicon. The thickness of the lightly doped, semiconducting layer 103 may be less than 40 nm or less than 20 nm. Further, a particularly thin, lightly doped, semiconducting layer 103 is preferred. In addition, a layer 104a or 104b, respectively, is applied to the upper side of the electrically insulating layer 102, adjacent to both sides of the lightly doped, semiconducting layer 103, which are formed from a highly doped semiconductor. The lightly doped semiconducting layer 103 separates the one highly doped semiconducting layer 104a from the other highly doped semiconducting layer 104b. The highly doped, semiconducting layer 104a can advantageously be thinner than the lightly doped, semiconducting layer 103, as shown in FIG. 1. In the case of silicon, the foreign atoms boron, indium, aluminum or gallium may be used for doping if p-type doping is to be achieved. In the case of silicon, the foreign atoms phosphorus, arsenic or antimony may be used for doping if n-type doping is to be achieved. This also applies to the case where germanium is used instead of silicon.

An electrical contact 105a and/or 105b is located on each highly doped, semiconducting layer 104a. The two contacts can consist of NiSi₂. The one highly doped, semiconducting layer 104a is extended in an L-shape in such a way that it separates one of the electrical contacts 105a from the lightly doped, semiconducting layer 103. The other highly doped semiconductive layer 104b is extended in an L-shape such that it separates the other electrical contact 105b from the lightly doped semiconductive layer 103. A dielectric layer 106 is applied to the lightly doped semiconductive layer 103, which, as shown, can also be located on the ends of the highly doped semiconductive layers 104a and 104b. The dielectric layer may consist of HfO₂. An electrical contact 107 is applied to the dielectric layer 106. The electrical contact 107 may consist of TiN.

The electrical conductivity of the highly doped, semiconducting layers 104a and 104b is greater than the electrical conductivity of the lightly doped, semiconducting layer 103 due to the higher doping.

The electrical contact 105a may serve as a source terminal. The electrical contact 105b may serve as a drain terminal. The electrical contact 107 may serve as a gate terminal. The doped layers may be p-doped.

A pulse with a negative voltage V_{D} of −0.3 V and a duration of 1 ms was applied to the drain terminal 105b of such a memory cell. No voltage was applied to the gate terminal 107 or to the source terminal 105a. After this pulse, the electrical current from source terminal 105a to drain terminal 105b was measured with a time delay of one second as a function of a time-varying voltage VDR of −0.30 volts applied to gate terminal 107. In addition, an electrical voltage of −0.30 V was applied to the drain terminal 105b. No voltage was applied to the source terminal 105a. This experiment was repeated with a pulse with a negative voltage V_{D}=−1.75 V and a time length of 1 ms.

FIG. 2 shows the measured current curves from source terminal 105a to drain terminal 105b as a function of the time-varying voltage V_{G} applied to gate terminal 107. The current-voltage curve is shown on the one hand for the case that a pulse V_{D}=−0.30 V has been previously applied and on the other hand for the case that a pulse V_{D}=−1.75 V has been previously applied. The voltage is a pulsed voltage.

During the measurement, the voltage VG applied to the gate terminal 107 was linearly varied over time from −1.0 V to +1.0 V. From a voltage V_{G} of −1.0 V applied to the gate terminal 107 to a voltage V_{G} of approximately +0.14 V applied to the gate terminal 107, the current ID dropped from 10⁻⁴ A to 10⁻¹⁴ A, according to the initially arcuate falling curve shown in FIG. 2. A voltage V_{G} of more than 0.14 V applied to gate terminal 107 did not change the measured currents I_{D}. The behavior of the transistor and/or the electric current flowing from the source terminal to the drain terminal, did not depend on the preceding voltage pulses V_{D}=−0.3 V and V_{D}=1.75 V.

FIG. 3 illustrates the application of a write pulse and a subsequent readout of the memory cell. A pulse with a negative voltage V_{DW}=−2.0 V and a duration of 1 ms was applied to the drain terminal 105b. No voltage was applied to the gate terminal 107 and the source terminal 105a during the writing. The height of the write pulse exceeded a limit V_{WT} determined by experiments. The limit V_{WT} determined by experiments was between −1.75 V and −2.0 V. After this write pulse, the curve of the current from the source terminal 105a to the drain terminal 105b was measured with a delay of one second as a function of a voltage V_{G} applied to gate terminal 107. In addition, a voltage V_{DR}=−0.30 V was applied to drain terminal 105b. The voltage V_{DR} was therefore below the limit value V_{WT}. No voltage was applied to the source terminal 105b. This experiment was repeated with further write pulses with other voltages, namely V_{DW}=−2.25 V, V_{DW}=−2.50 V and V_{DW}=−2.75 V. However, a voltage can also be applied to the source terminal 105b for collecting charge carriers and storing, which in the example given also lies between −1.75 V and −2.0 V.

FIG. 4 shows the measured current curves of the current from the source terminal 105a to the drain terminal 105b. Comparison of the measured current curves with the current curve already shown in FIG. 2 for the case V_{D}=−0.30 V shows that applying pulsed voltages V_{DW}=−2.00 V, V_{DW}=−2.25 V, V_{DW}=−2.50 V and V_{DW}=−2.75 V changes the current flow from the source terminal 105a to the drain terminal 105b. This change is illustrated for the case V_{DW}=−2.00 V by an added ΔV, which shows the change in the threshold voltage between the current curve from FIG. 2 for the case V_{D}=−0.30 V and the current curve after application of V_{DW}=−2.00 V. The current ID only reached the current strength of 10¹⁴ A at a voltage Vo of approx. 0.33 V applied to the gate terminal 107. FIG. 4 further illustrates that the current after applying write pulses V_{DW} also depends on the magnitude of the voltage. The larger the magnitude of the voltage V_{DW} was, the larger was ΔV and the voltage V_{G} needed for the current Ip to reach the current strength of 10¹⁴ A. From this it follows that several different states can be stored by the memory cell. In this sense, the memory cell enables a logic with several states and in this sense an analog storage of information.

FIG. 5 clarifies the technical background for the case that a write pulse Vow is applied to the drain terminal 105b and no voltage is applied to the source terminal 105a and no voltage is applied to the gate terminal 107, if the magnitude of the write pulse V_{DW} exceeds the magnitude of the threshold value V_{WT}. By such a write pulse Vow, charge carriers are generated, with the result that electrons accumulate at the upper side of the substrate 101 below the lightly doped, semiconducting layer 103. For this reason, the upper side of the substrate 101 comprises a surface or surface area for collecting charge carriers. This surface area is important for storing information because it changes the behavior of the transistor of the memory cell.

In addition, electron holes accumulate at the upper side of the substrate 101 below the drain terminal 105b. Therefore, there is a second section of a surface where charge carriers accumulate. This second area is not important for storing information, since it does not influence the behavior of the transistor, or at least not to any practical extent.

If the temperature of the memory cell is close to absolute zero, this prevents the electrons from timely recombining with the holes. The information then remains stored almost permanently. It is therefore advantageous to operate the memory cell at very low temperatures. At very low temperatures, the substrate is frozen and behaves like an electrical insulator or at least like an electrical resistor. The section near 102 has what is known as a “floating-body effect”. This means that this section is not connected to a line and can therefore accumulate charges.

The information stored in this way can be erased by an erase pulse VDE, which differs from the write pulse V_{DW} in polarity. If a write pulse V_{DW}=−x [V] was applied, the information stored by this can, in principle, be erased by an erase pulse V_{DE}=(x+y) [V], wherein x>0 and y≥0. The erase pulse causes a recombination of the previously collected charge carriers. Erasure can therefore be carried out by first reading the state of the memory cell and then using a pulse of a suitable polarity and a suitable length and/or height to achieve a recombination of the collected charge carriers. The height of the pulse refers to the electrical voltage in volts. Erasure is illustrated in FIG. 6. A 1 ms long write pulse with a voltage V_{DW}−2.75 V was applied to the drain terminal 105b. The dashed line shows the resulting current-voltage curve relative to the current-voltage curve with V=−0.3 V, which was measured before a write pulse. A 1 ms erase pulse VDE was later applied to the drain terminal 105b. Three such experiments were performed with three different erase voltages, namely V_{DE}=2.0 V, V_{DE}=2.2 V and V_{DE}=3.0 V. FIG. 6 shows that complete erasure was only achieved with a voltage V_{DE}=3.0 V.

FIG. 7 shows the effect on a current I_{D} of the source terminal 105a to the drain terminal 105b at a given gate voltage VG when write pulses V_{DW}=−2.5 V with a length of 100 ns are applied to the drain terminal 105b at 100 ns time intervals. FIG. 7 shows the electric current Ip as a function of the number of pulses. In addition, FIG. 7 shows the voltage curve V_{D} at the drain terminal 105b over time t. The temperature of the memory cell was 5.5 K. FIG. 7 shows that the current Ip increases with the number of pulses, according to an arched curve. The memory cell thus behaved like a biological synapse.

FIG. 8 shows a section of a second memory cell. This differs from the memory cell shown in FIG. 1 in the absence of an intermediate layer between the electrically insulating layer 102 and the electrical contacts 105a and 105b. Further, a section of such a memory cell is shown which has been produced in reality and viewed with an electron microscope.

FIG. 9 shows a section of a third memory cell that may comprise an SOI, also known as “silicon-on-insulator”. On a substrate 101a there is an electrically insulating layer 101b. On the electrically insulating layer 101b there is a layer 101 for collecting charge carriers. The substrate 101a may consist of silicon. The electrically insulating layer 101b can be buried oxide, i.e., BOX. The layer 101 for collecting charge carriers can be the uppermost silicon layer of the SOI component. FIG. 9 shows a recorded (stored) state. In the layer 101 for collecting charge carriers, charge carriers are collected, which is represented by the “−” and “+” signs. The advantage of this structure consists in the fact that the operating temperature is increased, since 101 also has a floating-body effect at room temperature. In principle, it can work as a memory at room temperature.

In one configuration, the source terminal is directly or indirectly on the electrically insulating layer. In one configuration, the drain terminal is directly or indirectly on the electrically insulating layer. When a terminal is indirectly on a layer, there are particularly one or more intermediate layers between the terminal and the layer. In one configuration, the layer for collecting charge carriers is not located directly on a gate terminal.

In one configuration, the layer for collecting charge carriers and/or the substrate of the memory cell is electrically insulated from the ground. In one configuration, the memory cell comprises an electrically insulating layer on the back of the layer for collecting charge carriers and/or the substrate. The back side is typically the side facing away from the electrically insulating layer on the surface provided for collecting charge carriers. This makes it possible to store the stored charges in the layer for collecting charge carriers and/or in the substrate for a significantly longer time, for example, several days, at room temperature. This can be used, for example, in “neuromorphic hardware”, such as technical systems based on neural systems and/or analog storage. “Neuromorphic hardware” requires dwell times of more than an hour, which is possible with this embodiment, even at room temperature.

The device, for example with a thin buried oxide layer, can also be used as an image sensor. Exposure to light creates holes and/or electrons in the substrate, which also changes the switching voltage and/or the switching current of the transistor. The combination of optics and memory can further expand the applications of the device.

A further aspect of the invention is a light and/or image sensor, in particular comprising a layer for collecting charge carriers at a surface of the layer, in particular comprising an electrically insulating layer on the surface provided for collecting charge carriers, in particular comprising a lightly doped semiconducting layer on the electrically insulating layer, in particular comprising a dielectric layer on the lightly doped semiconducting layer, in particular comprising an electrical contact serving as a gate terminal on the dielectric layer, in particular comprising an electrical contact serving as a source terminal, in particular with an electrical contact serving as a drain terminal, wherein the dielectric layer is located in particular between the source terminal and the drain terminal. All features, advantages and embodiments of the above-mentioned memory cell also apply to the image sensor and vice versa.

1. Method for operating a memory cell comprising a layer (101) for collecting charge carriers at a surface of the layer (101), an electrically insulating layer (102) on the surface provided for collecting charge carriers, a lightly doped semiconducting layer (103) on the electrically insulating layer (102), a dielectric layer (106) on the lightly doped semiconducting layer (103), an electrical contact (107) serving as a gate terminal on the dielectric layer (106), an electrical contact serving as a source terminal (105a), an electrical contact serving as a drain terminal (105b), wherein the dielectric layer (106) is between the source terminal (105a) and the drain terminal (105b), so that the drain terminal (105b) and the source terminal (105b) are not located on the dielectric layer, characterized in that information is stored in the memory cell and/or information is read from the memory cell by applying an electrical voltage to the drain terminal (105b), wherein the magnitude of the electrical voltage for reading is lower than the magnitude of the electrical voltage for storing information.

2. Method according to the preceding claim, characterized in that the source terminal (105a) is separated from the dielectric layer (106) by a highly doped semiconductor (104a) and/or the drain terminal (105b) is separated from the dielectric layer (106) by a highly doped semiconductor (104b).

3. Method according to one of the preceding claims, characterized in in that the source terminal (105a) is separated from the electrically insulating layer (102) by a highly doped semiconductor (104a) and/or the drain terminal (105b) is separated from the electrically insulating layer (102) by a highly doped semiconductor (104b).

4. Method according to one of the preceding claims, characterized in that the dielectric layer (106) is at most 20 nm or at most 15 nm thick or at most 10 nm.

5. Method according to one of the preceding claims, characterized in that the layer (101) for collecting charge carriers is the substrate of the memory cell.

6. Method according to one of the preceding claims, characterized in that the layer (101) for collecting charge carriers is formed from a lightly doped semiconductor and/or in that the electrically insulating layer is formed from silicon dioxide, silicon nitride, hafnium oxide, zirconium oxide or aluminum oxide and/or that lightly doped silicon is used as the lightly doped semiconductor and/or that the gate, source and/or drain terminal (105b) are formed from silicide or Al, Cu, Cr, W, TIN.

7. Method according to one of the preceding claims, characterized in that the memory cell is configured such that information can be stored in the memory cell and/or information can be read out of the memory cell by applying an electrical voltage to the drain terminal (105b), wherein the magnitude of the electrical voltage for reading is lower than the magnitude of the electrical voltage for storing information.

8. Method according to one of the preceding claims, characterized in that a lightly doped semiconducting layer has a doping of at most 1e17 cm⁻³ and/or in that a highly doped semiconducting layer has a doping of at least 1e18 cm⁻³.

9. Method according to one of the preceding claims, characterized in that the memory cell is configured such that information can be stored in the memory cell by applying an electrical voltage to the drain terminal (105b) in the form of electrical pulses, and the stored information depends on the number of pulses.

10. Method according to one of the preceding claims, characterized in that information in the memory cell is erased by applying a voltage to the drain terminal (105b), the polarity of which is the reverse of the polarity of the voltage for storing information.

11. Method according to one of the preceding claims, characterized in that information is stored in the memory cell by applying an electrical voltage in the form of a plurality of electrical pulses to the drain terminal (105b).

12. Method according to the preceding claim, characterized in that information stored in the memory cell depends on the number of pulses.

13. Method according to one of the preceding claims, characterized in that the memory cell is operated at a temperature of less than 200 K or less than 10 K.

14. Method according to one of the preceding claims, characterized in that the voltage applied to the drain terminal (105b) for storing information and for reading information is negative when the highly-doped semiconducting layer (104) and (101) is p-doped, and that the voltage applied to the drain terminal (105b) for storing information and for reading information is positive when the highly-doped semiconducting layer (104) and (101) is n-doped.

15. Method according to one of the preceding claims, characterized in that the memory cell is operated at cryogenic temperatures.
